(19) United States
(12) Patent Application Publication
(10) Pub. No.: US 2013/0106427 A1
(43) Pub. Date: May 2, 2013

(54) Battery Rating Method

(71) Applicants: John Harold Miller, Johns Creek, GA (US); Layna Lanier Mendlinger, Alpharetta, GA (US); Travis Zachary Torrey, Sugar Hll, GA (US)

(72) Inventors: John Harold Miller, Johns Creek, GA (US); Layna Lanier Mendlinger, Alpharetta, GA (US); Travis Zachary Torrey, Sugar Hll, GA (US)

(73) Assignee: EXIDE TECHNOLOGIES, Milton, GA (US)

(21) Appl. No.: 13/663,759

(22) Filed: Oct. 30, 2012

Related U.S. Application Data
(60) Provisional application No. 61/553,516, filed on Oct. 31, 2011.

(51) Int. Cl. G01R 31/36

(52) U.S. Cl. 324/430; 324/426

(57) ABSTRACT

A method of rating a battery includes providing a plurality of numerical values by removing units from standardized ratings or tests for the battery; assigning a pre-calculated unit scaling factor to each numerical value of the plurality of numerical values; and calculating a total rating by multiplying each pre-calculated unit scaling factor by each corresponding numerical value of the plurality of numerical values to obtain a normalized value for each numerical value of the plurality of numerical values, and adding each normalized value.

### FIELD OF THE INVENTION

This application claims priority to U.S. Provisional Application Ser. No. 61/553,516, filed Oct. 31, 2011, the subject matter of which is incorporated by reference in its entirety.

The present disclosure relates generally to the field of batteries and more specifically to battery rating methods.

### BACKGROUND OF THE INVENTION

Currently, batteries used in automotive applications are rated and advertised by “cold cranking amps” (CCA) and “reserve capacity” (RC). The tests used for these ratings are standardized and governed by various automotive battery organizations (e.g., Society of Automotive Engineers (SAE), Battery Council International (BCI), and Verband der Automobileindustrie (VDA)). CCA is defined as the current a battery can deliver at 0 degrees Fahrenheit (° F.) (18° C. (degrees Celsius)) for 30 seconds and maintain at least 1.2 volts per cell (7.2 volts for a 12-volt battery). RC is defined as the time (in minutes) that a battery at 80 ° F. (27 ° C.) will continuously deliver 25 amperes before the voltage drops below 10.5 volts.

While CCA and RC provide some information to a potential battery purchaser about battery performance, for new applications such as stop-start applications emerging for micro-hybrid electric vehicles (μHEVs), these ratings fail to provide information on the overall battery performance needed for these new applications. Micro-hybrid vehicles are different from conventional vehicles, as they are designed to shut the engine off when the vehicle comes to a stop. The engine is then restarted immediately before the vehicle begins moving again. As a result, the battery is forced to discharge during the period the engine is off to provide support for electrical loads in the vehicle and also discharge at a high rate to start the vehicle. This will happen many times during a normal trip as opposed to only once for a conventional vehicle. The battery therefore will discharge many times and be required to recharge quickly in order to replenish the charge depleted during the stop event to allow the vehicle to complete subsequent stop-start events.

Accordingly, a need has developed for a battery rating method to define an overall battery performance to assist users in selecting batteries.

### SUMMARY OF THE INVENTION

Disclosed herein are methods of rating batteries that are used to define an overall battery performance.

In one embodiment, a method of rating a battery comprises providing a plurality of numerical values by removing units from standardized ratings or tests for the battery; assigning a pre-calculated unit scaling factor to each numerical value of the plurality of numerical values; and calculating a total rating by multiplying each pre-calculated unit scaling factor by each corresponding numerical value of the plurality of numerical values to obtain a normalized value for each numerical value of the plurality of numerical values, and adding each normalized value.

In one embodiment, a method of rating a battery comprises providing a first numerical value by removing the units for cold cranking amp rating obtained according to SAEj537; providing a second numerical value by removing units for a reserve capacity rating obtained per SAE j537; providing a third numerical value by removing units for charge acceptance obtained per SAE j537; assigning a pre-calculated unit scaling factor to each the first, second and third numerical values; and calculating a total rating by multiplying each pre-calculated unit scaling factor by each corresponding first, second and third numerical value to obtain a normalized value for the first, second and third numerical value, and adding each normalized value.

In one embodiment, a method of rating a battery comprises providing a first numerical value by removing the units for cold cranking amp rating obtained according to SAEj537; providing a second numerical value by removing units for a reserve capacity rating obtained per SAE j537; providing a third numerical value by removing units for charge acceptance test obtained per SAE j537; providing a fourth numerical value by removing units for SAE j2801; assigning a pre-calculated unit scaling to each of the first, second, third and fourth numerical values; and calculating a total rating by multiplying each assigned pre-calculated unit scaling factor by each corresponding first, second, third and fourth numerical value to obtain a normalized value for the first, second, third and fourth numerical value, and adding each normalized value.

The above-described and other features will be appreciated and understood by those skilled in the art from the following detailed description, drawing, and appended claims.

### BRIEF DESCRIPTION OF THE DRAWINGS

FIG. 1 is a flow diagram of a battery rating method according to an exemplary embodiment.

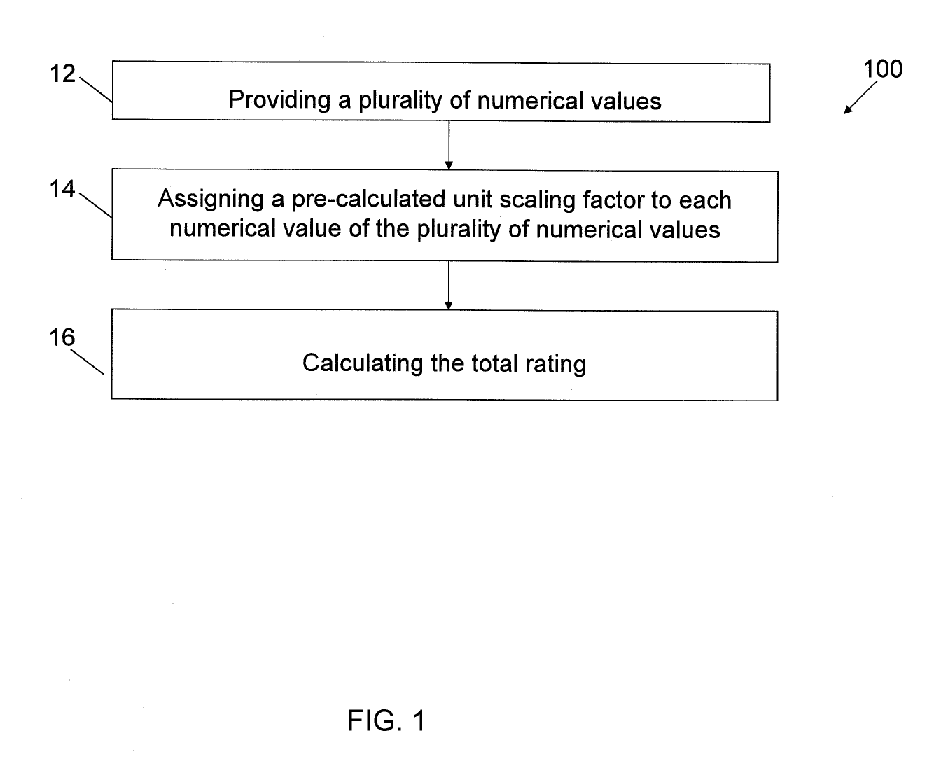

### DETAILED DESCRIPTION OF THE INVENTION

Disclosed herein are methods of rating batteries that are used to define an overall battery performance. While reference is made throughout this disclosure to automotive applications and automotive standardized ratings, it is to be understood that the claimed invention can apply to other battery applications (e.g., motive power and industrial applications). Additionally, it is to be understood that as new standardized ratings and/or tests are developed by various organizations, it is envisioned for the claimed invention to include those ratings and/or tests as well.

The term “standardized” or “standard” is used throughout this disclosure in reference to various ratings and/or test protocols. The term standardized or standard is intended to refer to any generally-accepted rating and/or test protocol from an organization that publishes rating or test protocols for battery rating or testing that provides a framework for rating or testing a battery. Examples of organizations that publish rating or test protocols include, but are not limited to, Society of Automotive Engineers (SAE), Battery Council International (BCI), and Verband der Automobileindustrie (VDA).

Referring now to the Figure, a flow diagram of an exemplary embodiment of a battery rating method 100 is illustrated. At block 12, a plurality of numerical values is provided. The numerical values are obtained by removing units from a plurality of standardized ratings or tests (e.g., amps removed from CCA rating). At block 14, a pre-calculated unit scaling factor is assigned to each numerical value of the plurality of numerical values from block 12 to normalize the magnitude of the numbers from various ratings (e.g., some ratings have numbers with only tens' place digits whereas others have hundreds' place digits). At block 16, a total rating is calculated. In one embodiment, a total rating is calculated by multiplying each pre-calculated unit scaling factor by each corresponding numerical value of the plurality of numerical values to obtain a normalized value for each numerical value of the plurality of numerical values, and adding each normalized value.

In one embodiment, the numerical values of plurality of numerical values from block 12 are selected by removing the units from at least two of the following standardized ratings or tests: Cold Cranking Amps (CCA) per SAE j537, Reserve Capacity (RC) per SAE j537; Charge Acceptance (CA) per SAE j537; 17.5% DOD Life cycle test per VDA 2010-03; Repeated Reserve Capacity (RRC) test per VDA 2010-03; and SAE j2801. Currently, test protocol for VDA 2010-3 is in draft form from VDA and is not readily available to the public, but is readily available to original equipment manufactures in draft form. Obtaining numerical values from j2801 and 17.5% DOD tests can be particularly beneficial in creating a rating useful for vehicles with underhood battery locations and low or no hybridization. In other embodiments, obtaining numerical values from 17.5% DOD and RRC tests can be particularly beneficial in creating a rating useful in hybrid electric vehicles (HEV) applications and in vehicle locations.

An advantage of the overall rating method disclosed herein is that it is based on numerical values from standardized test protocols. Specifically, potential battery customers have grown accustomed to standardized ratings from various organizations. It is believed that consumer acceptance and understanding of the disclosed overall rating method for batteries is enhanced compared to a rating system that is based upon non-standardized ratings. Further, the overall rating methods disclosed herein can allow a potential battery customer to compare batteries across various manufacturers and different battery chemistries (e.g., lithium-ion compared to lead-acid batteries). Additionally, as a standardized rating loses its relevance (e.g., CCA) in selecting a battery, a need will still exist for an overall battery rating. The claimed invention provides flexibility by allowing new standardized ratings to be entered into the algorithm to create a new overall rating.

Turning now to the pre-calculated unit scaling factor employed in block 14. Since the overall rating system is based upon numerical values from standardized ratings, the relative number magnitude (scale) of each rating can vary significantly. For example, CCA is presented as a number with a hundreds' digit (e.g., 925), whereas RRC is presented as a number with only a tens' digit (e.g., 15). The scaling factor is a means of normalizing the relative magnitude to provide a rating with the desired number of digits. In some embodiments, it is desirable to have a scaling factor that will normalize the scale to a hundreds' digit. Without wanting to be bound to theory, it is believed that since consumers have familiarity with ratings such as CCA that are on the hundreds' digit scale, a rating with a hundreds' digit can aid with acceptance and understanding of the total rating method. However, in one embodiment, to avoid consumer confusion with current CCA ratings, the total rating should be normalized to be a least 200 less than the numerical value of the CCA rating of the battery. An example of one embodiment of calculating the scaling factor is discussed in the Example section below. It is to be understood that while a weighting factor is used to “solve for” the scaling factor, the scaling itself is different than a weighting factor.

An embodiment of the method of rating a battery can be embodied in the form of computer-implemented processes and apparatuses for practicing those processes. The method can also be embodied in the form of a computer program product having computer program code containing instructions embodied in tangible media, such as floppy diskettes, CD-ROMs, DVDs, hard drives, universal serial bus (USB) drives, or any other computer-readable storage medium, such as random access memory (RAM), read only memory (ROM), or erasable programmable read only memory (EPROM), for example, wherein, when the computer program code is loaded into and executed by a computer, the computer becomes an apparatus for practicing the method. The method can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein when the computer program code is loaded into and executed by a computer, the computer becomes an apparatus for practicing the method. When implemented on a general-purpose microprocessor, the computer program code segments configure the microprocessor to create specific logic circuits.

### EXAMPLE

In this example, the total battery rating method was based on five standardized tests: cold cranking amp (CCA) rating obtained according to SAE j537); reserve capacity (RC) rating obtained per SAE j537; 17.5% DOD Life cycle test per VDA 2010-03(test protocol is in draft form and is not yet formally approved, but is readily available to various original equipment manufactures in draft form); static charge acceptance test obtained per SAE j537; and SAE j2801.

Next, a total baseline total score was set at 100. The baseline score number 100 was selected because it was less than the typical CCA value, to allow the total rating scale to be distinguishable from a CCA rating to a consumer. Each of the five standardized test values was assigned an equal weight. Specifically, a weighting factor of 20% was assigned to each of the five standardized test values to obtain an individual score component of 20 (i.e., 0.2×100=20).

Baseline values of each of the standardized tests was then determined. For CCA and RC, the baseline value was calculated by obtaining the midpoint average rating printed on the batteries accounting for top 10 battery sizes based on unit sales volume. For 17.5% DOD, the baseline value was determined by VDA minimum requirement of 6 weeks for a flooded battery. For static discharge acceptance, the baseline value was calculated using 3% of midpoint average, which is an expected value as determined by SAE j537. For j2801, the baseline value was determined by counting the number of cycles over a 10 week period of testing.

Next, a scale factor is “solved for” using the baseline score and the individual score component of the total score. For example, for CCA, the scaling factor was calculated utilizing the following equation: Baseline CCA x Scaling factor=20 (where the number 20 was previously calculated as 20% of the total score). Here the baseline CCA midpoint was calculated at 542. Solving for the unknown scaling factor resulted in a scaling factor of 0.369

Table 1 illustrates the baseline input values, the calculated score factor and the score points.

TABLE 1

| | Base line values | | |
|---|---|---|---|
| | (units removed) | Calculated Scaling factor | Score Points |
| CCA | 542.25 | 0.36883 | 20 |
| RC | 100.35 | 0.19930 | 20 |
| 17.5% DOD | 510 | 0.039216 | 20 |
| Static Charge | 16.268 | 1.2294 | 20 |
| acceptance | | | |
| J2801 | 340 | 0.058824 | 20 |

Now that the scale factor has been calculated, a total performance battery rating can be determined on any battery. A test case was performed as illustrated in Table 2 below:

TABLE 2

| | | Pre-Calculated Scaling | Calculated Score |
|---|---|---|---|
| | Input Value | factor | Points |
| CCA | 730 | 0.36883 | 26.925 |
| RC | 140 | 0.19930 | 27.902 |
| 17.5% DOD | 255 | 0.039216 | 10 |
| Static Charge | 18.42 | 1.2294 | 22.646 |
| acceptance | | | |
| J2801 | 306 | 0.058824 | 18 |
| | | Total Battery Rating = | 105.47 |

The benefit given by using a system like this creates a “general use” estimation of capabilities as the chosen tests allow for a wide range of uses for the battery. The higher the composite score number the greater the overall lifetime performance of the battery. This gives the consumer a metric that will have a direct affect on how the battery performs over a period of time instead of looking purely at initial performance in only a few of the categories that affect the user. The “general use” allows the metric to be an effective measure of performance for a wide range of consumers.

This measurement system was design to allow for a simple final calculation that can be interpreted by the end user in general terms. The worst possible battery becomes a zero composite score and there is no cap on how high a composite score can be, thereby allowing for future technologies to be calculated and compared numerically.

While the invention has been described with reference to an exemplary embodiment, it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method of rating a battery, comprising:
providing a plurality of numerical values by removing units from standardized ratings or tests for the battery;
assigning a pre-calculated unit scaling factor to each numerical value of the plurality of numerical values; and
calculating a total rating by multiplying each pre-calculated unit scaling factor by each corresponding numerical value of the plurality of numerical values to obtain a normalized value for each numerical value of the plurality of numerical values, and adding each normalized value.

2. The method of claim 1, wherein numerical values are obtained utilizing at least two standardized ratings or tests selected from the group consisting of: cold cranking amps per SAE j537, reserve capacity per SAE j537, charge acceptance per SAE j537, and SAEj2801.

3. The method of claim 1, wherein the unit scaling factor is selected such that the total rating is a numerical value having a hundreds' place digit and is at least 200 less than a numerical value calculated for the cold cranking amp.

4. A method of rating a battery, comprising:
providing a first numerical value by removing the units for cold cranking amp rating obtained according to SAEj537;
providing a second numerical value by removing units for a reserve capacity rating obtained per SAE j537;
providing a third numerical value by removing units for charge acceptance obtained per SAE j537;
assigning a pre-calculated unit scaling factor to each the first, second and third numerical values; and
calculating a total rating by multiplying each pre-calculated unit scaling factor by each corresponding first, second and third numerical value to obtain a normalized value for the first, second and third numerical value, and adding each normalized value.

5. The method of claim 4, wherein the unit scaling factor is selected such that the total rating is a numerical value having a hundreds' place digit and is at least 200 less than first numerical value.

6. A method of rating a battery, comprising:
providing a first numerical value by removing the units for cold cranking amp rating obtained according to SAEj537;
providing a second numerical value by removing units for a reserve capacity rating obtained per SAE j537;
providing a third numerical value by removing units for charge acceptance test obtained per SAE j537;
providing a fourth numerical value by removing units for SAE j2801;
assigning a pre-calculated unit scaling to each of the first, second, third and fourth numerical values; and
calculating a total rating by multiplying each assigned pre-calculated unit scaling factor by each corresponding first, second, third and fourth numerical value to obtain a normalized value for the first, second, third and fourth numerical value, and adding each normalized value.

7. The method of claim 6, wherein the total rating value is a least 200 less than the first value.
